(19) United States
(12) Patent Application Publication
(10) Pub. No.: US 2022/0104361 A1
(43) Pub. Date: Mar. 31, 2022

(54) Interposer For Printed Circuit Boards

(71) Applicant: SOFTIRON LIMITED, Chilworth (GB)

(72) Inventors: Robert Drury, Fotherby. Louth (GB); Sean Michael Burdick, San Jose, CA (US)

(73) Assignee: SOFTIRON LIMITED, Chilworth (GB)

(21) Appl. No.: 17/486,856

(22) Filed: Sep. 27, 2021

Related U.S. Application Data
(60) Provisional application No. 63/084,382, filed on Sep. 28, 2020.

(51) Int. Cl. H05K 3/40

(52) U.S. Cl. CPC H05K 3/4007; H05K 2201/042; H05K 2201/09945; H05K 2201/10598; H05K 2201/094; H05K 2201/10568

(57) ABSTRACT

A system includes a top printed circuit (PCB) including an array of contact pads, a bottom PCB including an array of contact pads, at least one interposer positioned between the top and bottom PCBs, including: an array of top connectors configured to contact the array of contact pads of the top PCB; an array of bottom connectors configured to contact the array of contact pads of the bottom PCB; and interconnections configured to electrically connect the top connectors and the bottom connectors, at least one spacer element positioned between the top PCB and the bottom PCB and configured to contribute to maintaining a specified distance between the top PCB and the bottom PCB; and at least one fastener of the top PCB and the bottom PCB. The system further includes fasteners configured to press the top PCB, the interposer, the bottom PCB, and the spacer layer together.

### PRIORITY

This application claims priority to U.S. Provisional Patent Application No. 63/084,382 filed Sep. 28, 2020, the contents of which are hereby incorporated in their entirety.

### FIELD OF THE INVENTION

The present disclosure relates to server and backplane connections between printed circuit boards (PCB). In particular, systems and methods are disclosed for connecting stacked PCBs via interposers that are stabilized via spacers and fasteners.

### BACKGROUND

In server and computing technology, an interposer may be used to connect signals between different PCBs, planes, motherboards, or other suitable entities. An interposer may include an electrical interface routing between one socket or connection to another. An example interposer may include an adapter to connect one or more auxiliary cards, backplanes, or other devices to a motherboard.

Interposers are constructed using several different methods. One such method for PCB to PCB connections is to use pads and springs to make the connection. On each PCB, an array of contact pads are created. Between the PCBs is an interposer. The interposer may include an array of spring connections. The spring connections may be located on the top and the bottom of the interposer to engage and contact each PCB. Connectivity between the PCBs may rely upon the springs of the interposer pressing against the designated pad of the respective PCB with sufficient pressure.

FIGS. 1A and 1B are illustrations of an example system for ancillary PCBs, wherein an interposer 10 is positioned between a top PCB 50 and a bottom PCB 52. In FIG. 1A, a top PCB 50 and a bottom PCB 52 may be connected via an interposer 10. Interposer 10 may include a substrate 12 with upper spring contacts 16 and lower spring contacts 18 attached thereto to connect to top PCB 50 and bottom PCB 52, respectively. Fasteners 54 may extend vertically through the PCBs 50 and 52 and interposer 10 to connectivity the spring contacts 16 and 18 with the PCBs 50 and 52. When functioning correctly, upper spring contacts 16 from interposer 10 interact with contact pads 51 on the bottom of top PCB 50. Similarly, when functioning correctly, lower spring contacts 18 from interposer 10 touch contact pads 53 on the top of the bottom PCB 52. Upper and lower spring contacts 16 and 18 may be connected by vias 14 and traces 13 through the substrate 12 of the interposer 10.

To apply sufficient forces to maintain contact between the spring contacts 16 and 18 of the interposer 10 and the PCBs 50 and 52, the fasteners 54 may be assembled to compress or squeeze the interposer 10 between the PCBs 50 and 52 so that the fasteners 54 are themselves in tension. When the fasteners 54 are in tension, they may apply opposing forces to the PCBs 50 and 52 to squeeze or compress the interposer 10. The separation distance between top PCB 50 and interposer substrate 12 may, according to vendor specifications, provide a proper amount of spring deflection and apply a proper force between the spring contacts 16 and pads 51 to make a complete electrical connection. Likewise, separation distance between bottom PCB 52 and interposer substrate 12 may, according to vendor specifications, provide a proper amount of spring deflection and apply a proper force between the spring contacts 18 and pads 53 to make a complete electrical connection.

As the pin count for a given interposer or between PCBs increases, the amount of area required to implement the connection increases accordingly. At a high density, a mechanical issue may arise. Such a mechanical issue may arise from the amount of compression pressure required to make all of the contact/pad connections between the interposer and the PCBs. At high compression pressure, the interposer may deflect or warp relative to the PCBs. Warping may cause the connectivity between the interposer spring connections and the PCB pads to be disrupted.

FIG. 1B illustrates a configuration where the bottom PCB 52 is warped. Some of the lower spring contacts 18 fail to make a connect/pad connection with pads 53 on the top surface of the bottom PCB 52. Incomplete electrical connection may be due to the deflection or warping of the bottom PCB 52, causing improper spacing between interposer 10 and bottom PCB 52. If the spacing is too large, one or more of spring contacts 18 may not touch with pads 53, which is the case for the spring contacts in the middle of the array. Furthermore, the warping may case the distance between bottom PCB 52 and interposer 10 to be too small such that one or more of the spring contacts 18 may be distorted and pressed out of position so that it does not interface with pad 53, which may be the case with the spring contacts 18 around the periphery of the array. Although example warping is shown for bottom PCB 52, warping may also occur in top PCB 50. This problem may be further exacerbated when multiple connections are made with multiple interposers in a stacked configuration.

Embodiments of the present disclosure may address one or more shortcomings of other interposer or PCB-PCB connection implementations.

### SUMMARY

Embodiments of the present disclosure may include a system. The system includes a top printed circuit board (PCB) including contact pads, a bottom PCB including contact pads, and one or more interposers. Each interposer includes top connectors configured to contact the contact pads of the top PCB, bottom connectors configured to contact the contact pads of the bottom PCB, and interconnections configured to electrically connect the top connectors and the bottom connectors. The system further includes a spacer layer in contact with a bottom of the top PCB and a top of the bottom PCB and configured to maintain a constant distance between the top PCB and the bottom PCB. The system further includes fasteners configured to press the top PCB, the interposer, the bottom PCB, and the spacer layer together.

In one embodiment, the system may include: a top printed circuit (PCB) including an array of contact pads; a bottom PCB including an array of contact pads; at least one interposer positioned between the top and bottom PCBs, including: an array of top connectors configured to contact the array of contact pads of the top PCB; an array of bottom connectors configured to contact the array of contact pads of the bottom PCB; and interconnections configured to electrically connect the top connectors and the bottom connectors; at least one spacer element positioned between the top PCB and the bottom PCB and configured to contribute to maintaining a specified distance between the top PCB and the bottom PCB; and at least one fastener of the top PCB and the bottom PCB.

In a further embodiment, a method of assembling elements in a socket cavity includes: positioning a bottom printed circuit (PCB) including an array of contact pads; positioning at least one interposer above the bottom PCB, wherein the at least one interposer comprises: an array of top connectors configured to contact the array of contact pads of the top PCB; an array of bottom connectors configured to contact the array of contact pads of the bottom PCB; and interconnections configured to electrically connect the top connectors and the bottom connectors; positioning at least one spacer element above the bottom PCB; and positioning a top PCB, including an array of contact pads, above the at least one spacer element; fastening the top PCB and the bottom PCB so that the at least one spacer element maintains a specified distance of separation between the top and bottom PCBs.

According to still another embodiment, a socket cavity comprises: a top printed circuit (PCB) including an array of contact pads; a bottom PCB including an array of contact pads; at least one floating interposer positioned between the top and bottom PCBs, including: an array of top spring connectors configured to contact the array of contact pads of the top PCB; an array of bottom spring connectors configured to contact the array of contact pads of the bottom PCB; and interconnections configured to electrically connect the top connectors and the bottom connectors; at least one spacer element positioned between the top PCB and the bottom PCB and configured to contribute to maintaining a specified distance between the top PCB and the bottom PCB; and at least one fastener of the top PCB, the at least one spacer element, and the bottom PCB.

### BRIEF DESCRIPTION OF THE DRAWINGS

A more complete understanding of the present embodiments may be acquired by referring to the following description taken in conjunction with the accompanying drawings, in which like reference numbers indicate like features.

FIGS. 1A-1B are illustrations of an example system for ancillary PCBs with a high density interposer.

FIG. 2 shows a cross-sectional side view of an interposer with spring contacts.

FIG. 3 shows a cross-sectional side view of an interposer with bump contacts and spring contacts.

FIGS. 4A and 4B illustrate side and top cross-sectional views of a socket cavity having an interposer positioned by two spacer elements between integrated circuit boards.

FIGS. 5A and 5B illustrate side and top cross-sectional views of a socket cavity having an interposer positioned by four spacer elements between an integrated circuit board and a PCB.

FIG. 6 shows a cross-sectional side view of a socket cavity having four PCBs and one interposer positioned by two spacer elements.

FIG. 7 illustrates a cross-sectional side view of a socket cavity having two PCBs and two floating interposers within a spacer element.

FIGS. 8A and 8B illustrate side and top cross-sectional views of a stacked socket cavity having two floating interposers and a floating middle PCB positioned by one spacer elements between top and bottom PCBs.

FIGS. 9A and 9B illustrate side and top cross-sectional views of a stacked socket cavity having two interposers positioned by four spacer elements between top, middle, and bottom PCBs.

FIG. 10 shows a perspective, exploded view of a high density connector design (interposer) with a spacer element and a stiffener support.

FIGS. 11A, 11B, and 11C illustrate side and top cross-sectional views of a socket cavity having a floating interposer positioned by a spacer elements between top and bottom PCBs, and having a stiffener support.

FIG. 12 illustrates an example construction of a spacer layer and a top support.

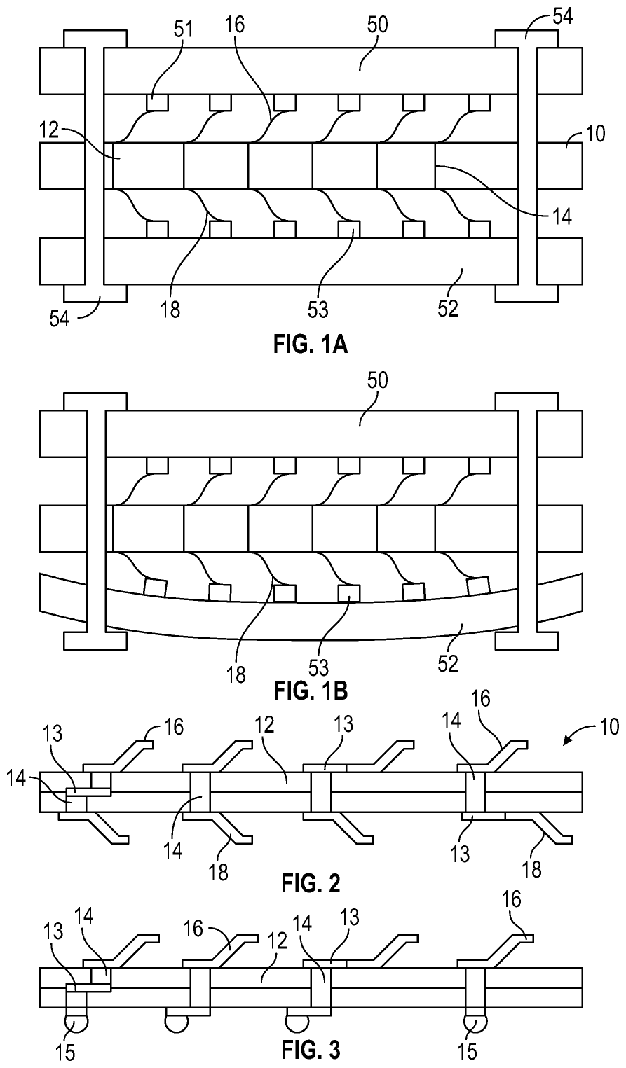

### DETAILED DESCRIPTION

Preferred embodiments are best understood by reference to FIGS. 2-12 below in view of the following general discussion. The present disclosure may be more easily understood in the context of a high level description of certain embodiments.

FIG. 2 illustrates a cross-section side view of an interposer 10 having spring contacts 16 on top and spring contacts 18 on bottom. The spring contacts 16 on the top may be connected to the spring contacts 18 on the bottom by vias 14. While the spring contacts 16 and 18 are generally positioned in a uniform array configurations, some of the spring contacts 16 and 18 may be offset laterally relative to the other spring contacts 16 and 18 in the arrays. For example, a trace 13 may extend laterally between a via 14 and a spring contact 16 or 18 so the spring contact 16 or 18 may be laterally offset. Traces 13 may be implemented at a surface of the substrate 12 or within the substrate 12.

FIG. 3 illustrates a cross-section side view of an interposer 10 having spring contacts 16 on the top of a substrate 12 and bump contacts 15 on a bottom of the substrate 12. The spring contacts 16 on the top may be connected to the bump contacts 15 on the bottom by vias 14. Traces 13 may be implemented at the surface or within the substrate 12 to laterally offset the spring contacts 11 and/or the bump contacts 15. Similar to the embodiment of FIG. 2, the spring contacts 16 and bump contacts 15 may be electrically interconnected through a network of traces 13 and vias 14 in and on substrate 12.

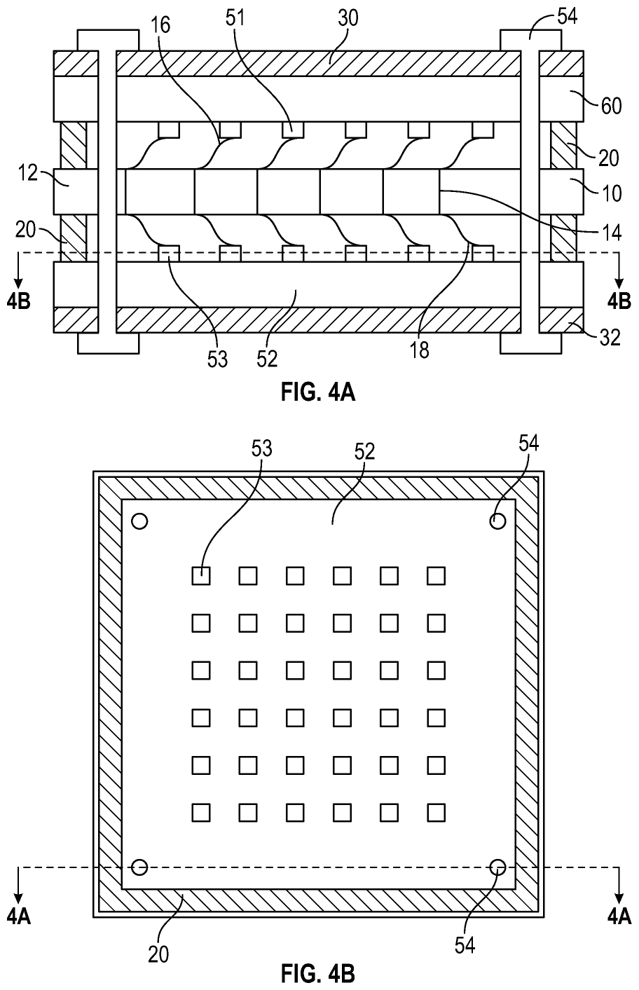

FIG. 4A shows a cross-section side view of a socket cavity having an interposer 10 assembled between a top integrated circuit board IC 60 and bottom PCB 52. Warping and/or nonuniform contact pressure may be resolved by adding spacer elements 20 and stiffening supports 30. FIG. 4A shows a spacer layer 20 may be configured to properly position the interposer 10 relative to the top integrated circuit board IC 60 and bottom PCB 52. The spacer element 20 may maintain a correct distance or separation between top integrated circuit board IC 60 and interposer 10, and a correct distance or separation between bottom PCB 52 and interposer 10. Correct distances may provide spring contacts of interposer 10 a desired touch pressure with contact pads 51 and 53 of boards 60 and 52. A compression or squeeze force applied by fasteners 54 may be counterbalanced by spacer element 20 to prevent the top integrated circuit board IC 60 and bottom PCB 52 from warping. Further, warping may also be inhibited by stiffening supports 30, which in some examples are reinforced silicon boards.

FIG. 4B illustrates a cross-sectional top view taken at B-B of FIG. 4A of the socket cavity having a spacer element 20 assembled on top of a bottom PCB 52. In this example, the spacer element 20 is square-shaped and is positioned around the fasteners 54 and the array of contact pads 53. Because the spacer element 20 is positioned outside of the fasteners 54, the spacer element 20 may prevent the separation distance between the bottom PCB 52 and the interposer 10 from getting too small as the fasteners 53 are tightened to squeeze the components in the socket cavity.

The interposer 10 may have upper spring contacts 16 on top surfaces and lower spring contacts 18 on bottom surfaces of a substrate 12. The spring contacts 16 and 18 may be electrically interconnected through a network of traces 13 and vias 14 in and on substrate 12. Interposer 10 in FIGS. 4A and 4B has upper spring contacts 16 to interface or pressure mate with contact pads 51 on an integrated circuit IC 60 such as a processor, and lower spring contacts 18 to interface or pressure mate with the contact pads 53 on a circuit board PCB 52 such as a computer motherboard. When a processor or other IC is placed in a socket, the integrated circuit board IC 60 sits directly on interposer 10, so that interposer 10 intercepts the signals to be routed between the integrated circuit board IC 60 and the outside of the socket cavity area. In the example of FIG. 4, upper spring contacts 16 may be spring contacts formed using cantilevered metal (e.g., copper) strips shaped to deflect when a retaining structure presses the terminals of the integrated circuit board IC 60 against the upper spring contacts 16. Similarly, lower spring contacts 18 in FIG. 4 may be spring contacts formed from metal strips shaped to compress against contact pads 53 on bottom printed circuit board PCB 52 when a retaining force is applied by fasteners 54. Metal traces 13, vias 14, or other electrical routings may also be on the top and bottom surfaces of substrate 12 and may be formed in the substrate 12. (See FIGS. 2 and 3). The traces 13, vias 14, or other electrical routings may be of the same material as or a different material from the material of spring contacts 16 and 18. Metal traces 13 may be patterned to conduct signals horizontally along the top or bottom or interior of the substrate 12. Vias 14 may be patterned to conduct signals vertically through the substrate 12, wherein traces 13 and vias 14 together may complete a conductive path between spring contacts on one side of the substrate 12 with spring contacts on the other side of the substrate 12.

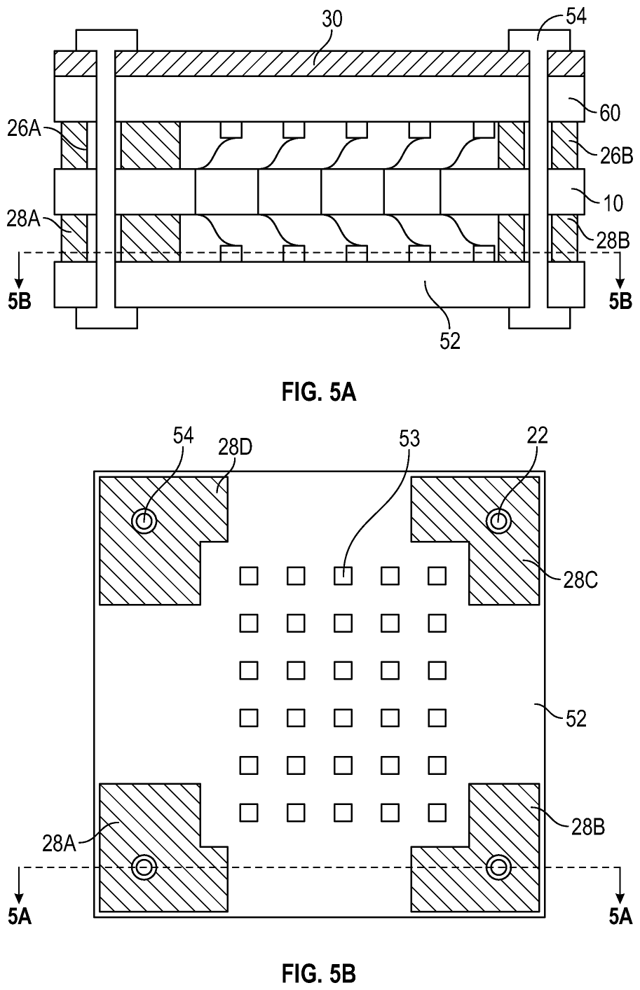

FIG. 5A shows a cross-sectional side view of a socket cavity taken at A-A of FIG. 5B and FIG. 5B illustrates a cross-sectional top view of the socket cavity taken at B-B of FIG. 5A. The illustrated socket cavity has an interposer 10 assembled between a top integrated circuit board IC 60 and bottom PCB 52. Eight spacer elements are included. Four spacer elements 26A-26D are between the interposer 10 and the top integrated circuit board IC 60. Four spacer elements 28A-28D are between the interposer 10 and the bottom PCB 52. In this example, the spacer elements 26A-26D and 28A-28D are elbow-shaped with a hole 22 in the middle and positioned so that the fasteners 54 extend through the holes 22. The spacer elements 26A-26D between the top integrated circuit board IC 60 and the interposer 10 and the spacer elements 28A-28D between the bottom PCB 52 and the interposer 10 may prevent separation distances from getting too small as the fasteners 54 are tightened to squeeze the components in the socket cavity. Correct distances may provide spring contacts of interposer 10 a desired touch pressure with pads 51 and 53 of boards 60 and 52. A compression or squeeze force applied by fasteners 54 may be counterbalanced by spacer elements 26A-26D and 28A-28D to inhibit the top integrated circuit board IC 60 and bottom PCB 52 from warping.

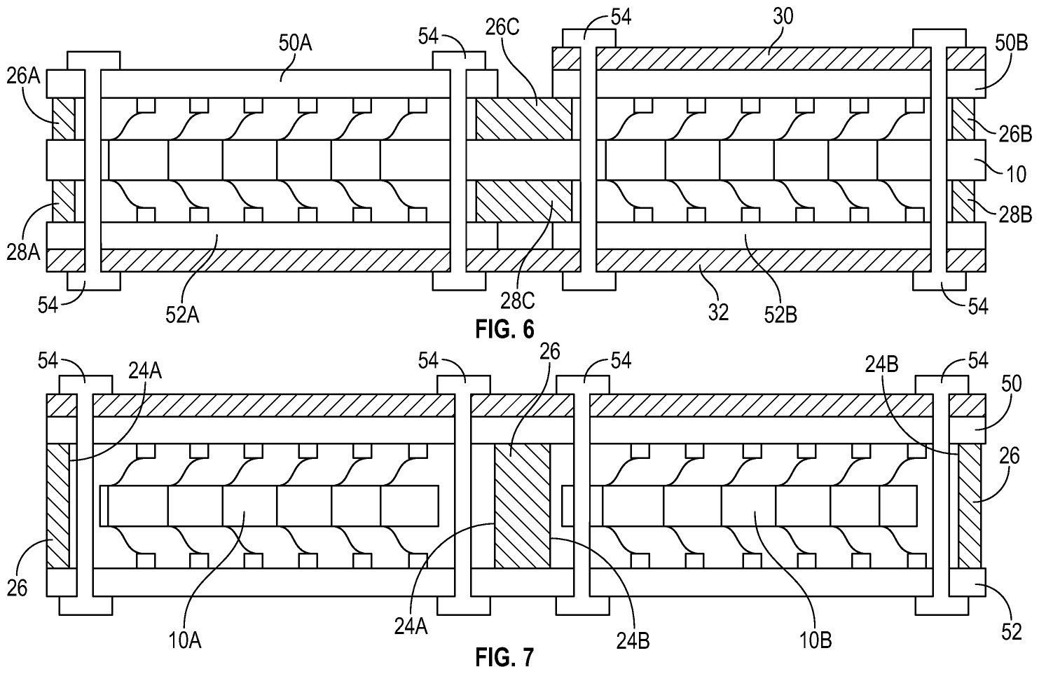

FIG. 6 shows a cross-sectional side view of a socket cavity having 2×2 PCBs and one interposer. This example has two top PCBs 50A and 50B and two bottom PCBs 52A and 52B in a side-by-side configuration. Six spacer elements are included. Three spacer elements 26A-26C are between the interposer 10 and the top PCB 50. Three spacer elements 28A-28C are between the interposer 10 and the bottom PCB 52. In this example, the spacer elements 26A-26C and 28A-28C are block-shaped elements and positioned near the fasteners 54. The spacer elements 26A-26C between the top PCB 50 and the interposer 10 and the spacer elements 28A-28C between the bottom PCB 52 and the interposer 10 may prevent separation distances from getting too small as the fasteners 54 are tightened to squeeze the components in the socket cavity.

FIG. 7 illustrates a cross-sectional side view of a socket cavity having two PCBs and two floating interposers. This example has a top PCB 50 and a bottom PCB 52. A spacer element 26 has a figure-8 shape and two openings 24A and 24B and is positioned between the top PCB 50 and the bottom PCB 52. A first interposer 10A is positioned in the opening 24A and a second interposer 10B is positioned in the opening 24B. The thickness of the spacer element 26 is specified to provide a correct separation distance between the top PCB 50 and a bottom PCB 52, so that the spring contacts of the interposers flex to apply a desired touch contact with the contact pads on the PCBs. The interposers 10A and 10B float in the openings 24A and 24B so that the forces applied by the spring contacts is distributed more evenly across both arrays of spring contacts. The spacer element 26 may prevent separation distances from being too small or too large as the fasteners 54 are tightened to squeeze the components in the socket cavity.

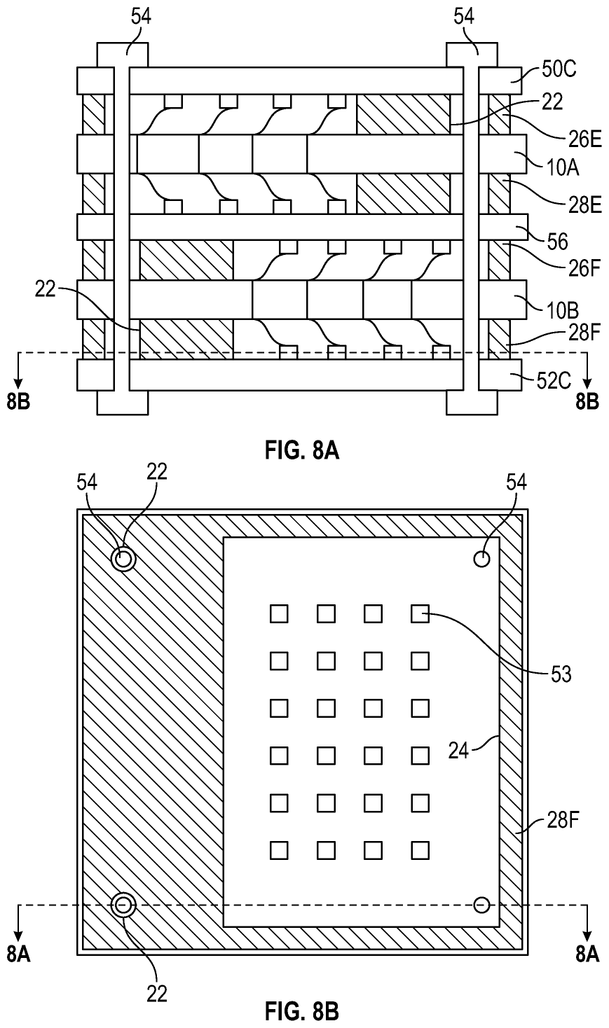

FIG. 8A shows a cross-sectional side view of a stacked socket cavity taken at A-A of FIG. 8B and FIG. 8B illustrates a cross-sectional top view of the stacked socket cavity taken at B-B of FIG. 8A. The illustrated stacked socket cavity has two interposers 10A and 10B assembled between PCBs 50C, 52C and 56. Middle PCB 56 has contact pads on both its top and bottom surfaces. Four spacer elements 26E, 28E, 26F, and 28F are included. Spacer element 26E is between interposer 10A and top PCB 50C. Spacer element 28E is between interposer 10A and middle PCB 56. Spacer element 26F is between interposer 10B and middle PCB 56. Spacer element 28F is between interposer 10B and bottom PCB 52C. As shown in FIG. 8B, the spacer element 28F is square-shaped with two holes 22 for passthrough of fasteners 54 and an opening 24 that encircles the contact pads 53 on the top surface of the bottom PCB 52C. In this example, the spacer elements 26F, 28E, and 26E are similarly configured as spacer element 28F, in that they also are square-shaped with two holes 22 for passthrough of fasteners 54 and openings 24 for encircling the contact pads 53 on the PCBs 50C, 52C and 56. In alternative stack socket cavity examples, the spacer elements may be different configurations, sizes, shapes, etc. to fit the needs of any PCB environment.

In the example of FIGS. 8A and 8B, the spacer elements 26E and 28E are positioned oppositely relative to spacer elements 26F and 28F. Spacer elements 26E and 28E have holes 22 positioned on the right side of the stacked socket and spacer elements 26F and 28F have holes 22 positioned on the left side of the stacked socket. The spacer elements 26E, 28E, 26E, and 28F may prevent separation distances from getting too small as the fasteners 54 are tightened to squeeze the components in the stacked socket cavity. Where the middle PCB 56 has contact pads on both its top and bottom surfaces, and the top contact pad array is shifted to the left and the bottom contact pad array is shifted to the fight, the separation distances between the interposers and the PCBs may become uneven when the fasteners 54 are tightened. The spring contacts of interposer 10A apply more contact force to the left side of middle PCB 56 and the spring contacts of interposer 10B apply more contact force to the right side of middle PCB 56. Spacer elements 26E and 28E are positioned opposite spacer elements 26F and 28F to oppose the unequal forces being applied by the offset spring contacts of the interposers 10A and 10B in view of the shifted contact pad arrays of middle PCB 56. Correct distances may provide spring contacts of interposers 10A and 10B a desired touch pressure with contact pads PCBs 50C, 56, and 52C. A compression or squeeze force applied by fasteners 54 may be counterbalanced by spacer elements 26E, 28E, 26F, and 28F to inhibit the PCBs and interposers from warping and to maintain correct separation distances.

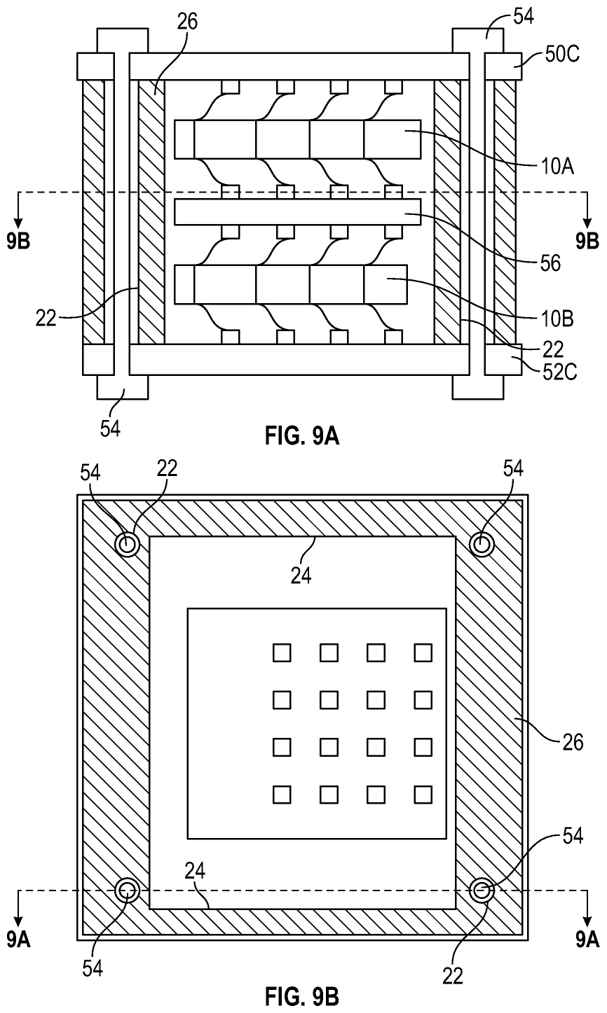

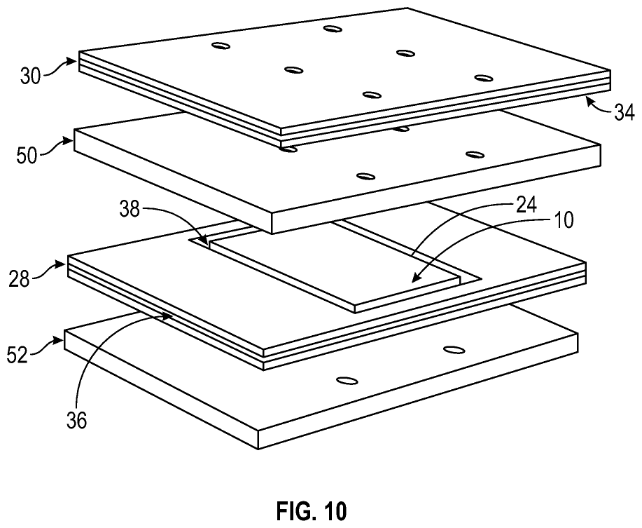

FIG. 9A shows a cross-sectional side view of a stacked socket cavity taken at A-A of FIG. 8B and FIG. 8B illustrates a cross-sectional top view of the stacked socket cavity taken at B-B of FIG. 8A. The illustrated stacked socket cavity has two interposers 10A and 10B assembled between PCBs 50C, 52C and 56. Middle PCB 56 has contact pads on both its top and bottom surfaces. One spacer element 26 is between top PCB 50C and bottom PCB 52C. As shown in FIG. 8B, the spacer element 26 is square-shaped with four holes 22 for passthrough of fasteners 54 and an opening 24 that encircles the middle PCB 50C and the two interposers 10A and 10B. The middle PCB 50C and the two interposers 10A and 10B float inside the opening 24 to allow the forces applied by the spring contacts is distributed more evenly across the arrays of spring contacts. The spacer element 26 may prevent separation distances between the top PCB 50C and the bottom PCB 52C from being too small or too large as the fasteners 54 are tightened to squeeze the components in the socket cavity.

According to some examples of the invention, one or more stiffening supports may be added to the socket cavity to inhibit PCB warpage and uneven separation distances between PCBs and interposers. For example, FIG. 4A shows a stiffener support 30 stacked on top of top integrated circuit board IC 60. The fasteners 54 extend through the stiffener support 30 so that when they are tightened, the stiffener support 30 is pressed against the top side of top integrated circuit board IC 60. The stiffener support 30 presses against the midsection of the top integrated circuit board IC 60 opposite the upper spring contacts 16 of the interposer 10, to maintain a constant separation distance between the top integrated circuit board IC 60 and the interposer 10. Another stiffener support 32 may be stacked below bottom PCB 52 as shown. Depending on the configuration of the PCBs and interposer, any combination of stiffener supports and spacer elements may be implemented to inhibit warpage and maintain separation distances. For example, FIG. 5A illustrates only one stiffener support 30 used in combination with spacer elements 26A-D and 28A-D. In another example shown in FIG. 6, two stiffener supports are used. The top stiffener support 30 is stacked only on PCB 50B. The bottom stiffener support 32 is stacked below both PCB 52A and PCB 52B. In some examples, a stiffener support extending across multiple PCB may inhibit the PCBs and interposers from warping and maintain correct separation distances.

FIG. 10 shows a perspective, exploded view of a high density connector design (interposer) with a spacer element and a stiffener support. In this example, a bottom PCB 52 is positioned at the bottom of a socket cavity. A bottom spacer element 28 and an interposer 10 are stacked on top of the bottom PCB 52. The bottom spacer element 28 has a conductive layer 36. The bottom spacer element 28 as an opening 24 in which the interposer 10 is placed. The outside dimensions of the interposer 10 are smaller than the inside dimensions of the opening 24 so that the interposer 10 fits within the opening 24 with mechanical separation 38 between. A top PCB 50 is stacked on the spacer element 28 and the interposer 10. A stiffener support 30 is stacked on the top PCB 50. The stiffener support 30 has a conductive layer 34. The additional conductive layers 34 and 36 may be used to reduce interference and crosstalk between the data signals in the top and bottom PCBs 50 and 52. Spacer layer 28 may ensure that a constant distance is maintained between upper PCB 50 and lower PCB 52. This may ensure that the physical separation required by interposer 10 is met. Spacer layer 28 may surround, laterally, interposer 10. In one embodiment, spacer layer 28 may be separate from interposer 10 without a mechanical connection therebetween. In another embodiment, spacer layer 28 may be mechanically connected or formed with interposer 10. The height of spacer layer 28 may be the specified, optimal, ideal, or preferred distance between PCBs 50 and 52 so as to engage or connect the pads thereof with the springs of interposer 10. Spacer layer 28 may have a mechanical separation 38 from interposer 10. Mechanical separation 38 may be lateral. Mechanical separation 38 may be large enough to prevent any thermal expansion between the two different materials of interposer 10 and spacer layer 28 from causing warping. Mechanical separation 38 may be small enough to ensure that warping of either PCB 50 and 52 is prevented. Spacer layer 28 may provide mechanical support to prevent deflections and warping.

Care should be taken in the physical construction of both spacer layer 28 and stiffener support 30. In one embodiment, materials for these components may be selected to not interfere with the data transmission of signals from upper PCB 50 or lower PCB 52. Additional conductive layers 34 and 36 may be added in the center of spacer layer 28 and stiffener support 30. Spacer layer 28 and stiffener support 30 may each be made from PCBs. Conductive layers 34 and 36 may reduce interference and crosstalk between the data signals in PCBs 50 and 52. In addition, conductive layers 34 and 36 may prevent electromagnetic interference (EMI) emissions for the connector assembly. In one embodiment, the conductive layers 34 and 36 may be connected to ground.

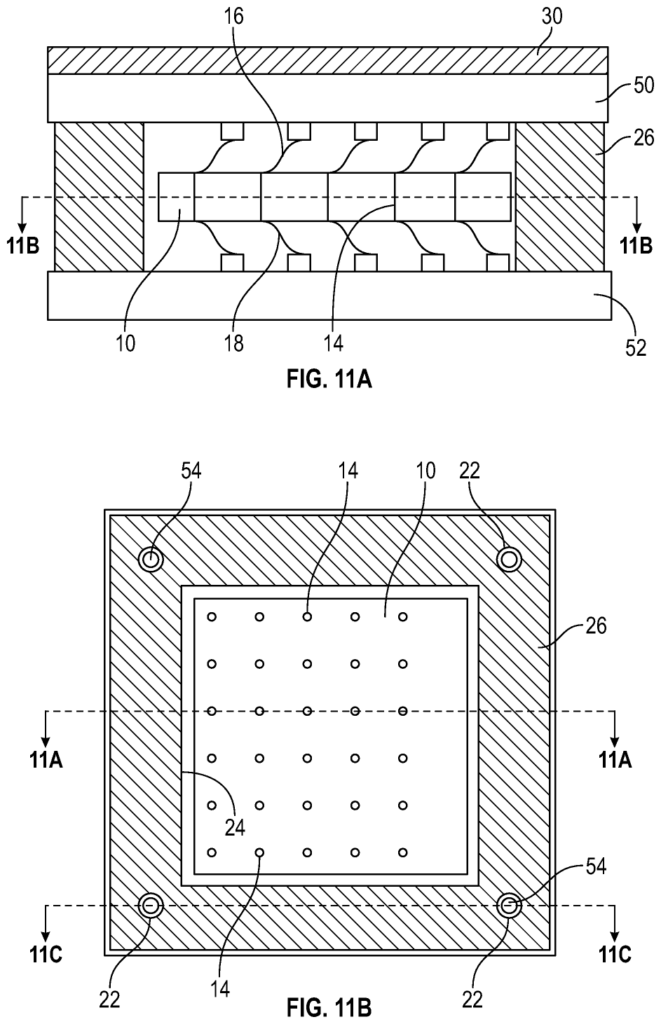

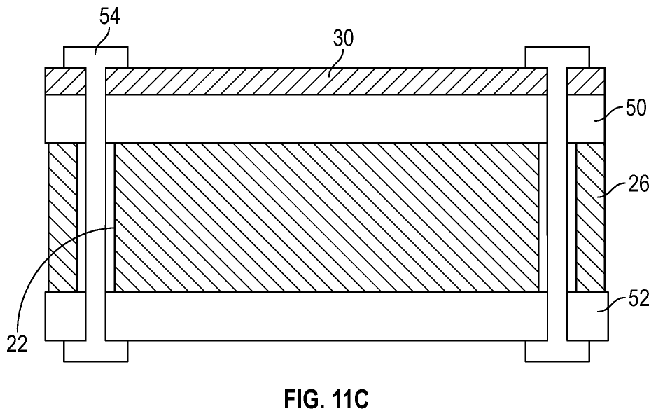

FIGS. 11A, 11B and 11C show side and top cross-sectional views of a socket cavity. FIG. 11A shows a cross-sectional side view of the socket cavity taken at A-A of FIG. 11B, which shows the middle section of the socket cavity. FIG. 11B illustrates a cross-sectional top view of the socket cavity taken at B-B of FIG. 8A, wherein an array of vias 14 in the interposer 10 are shown. FIG. 11C shows a cross-sectional side view of the socket cavity taken at C-C of FIG. 11B, which shows a section through the fasteners 54. The illustrated socket cavity has one interposer 10 assembled between PCBs 50 and 52. One spacer element 26 is between top PCB 50 and bottom PCB 52. As shown in FIG. 11B, the spacer element 26 is square-shaped with four holes 22 for passthrough of fasteners 54 and an opening 24 that encircles the interposer 10. The interposer 10 floats inside the opening 24 to allow the forces applied by the upper and lower spring contacts 16 and 18 is distributed more evenly across the arrays of spring contacts. The spacer element 26 may prevent separation distances between the top PCB 50 and the bottom PCB 52 from being too small or too large as the fasteners 54 are tightened to squeeze the components in the socket cavity.

Further, a stiffener support 30 is stacked on top of top PCB 50. The fasteners 54 extend through the stiffener support 30 so that when they are tightened, the stiffener support 30 is pressed against the top side of top PCB 50. The stiffener support 30 presses against the midsection of the top PCB 50 opposite the upper spring contacts 16 of the interposer 10, to maintain a constant separation distance across the array of upper spring contacts 16 between the interposer 10 and the top PCB 50. Stiffener support 30 may prevent further prevent warping. Referring again to FIG. 11A, spacer element 26 is sandwiched between the top PCB 50 and bottom PCB 52. This provides a constant distance between these PCBs, including interposer 10, prevents displacement and ensures connectivity. The stiffener support 30 may span all of instances of interposer 10 to prevent any displacement across the full set of interposers 10 in the system.

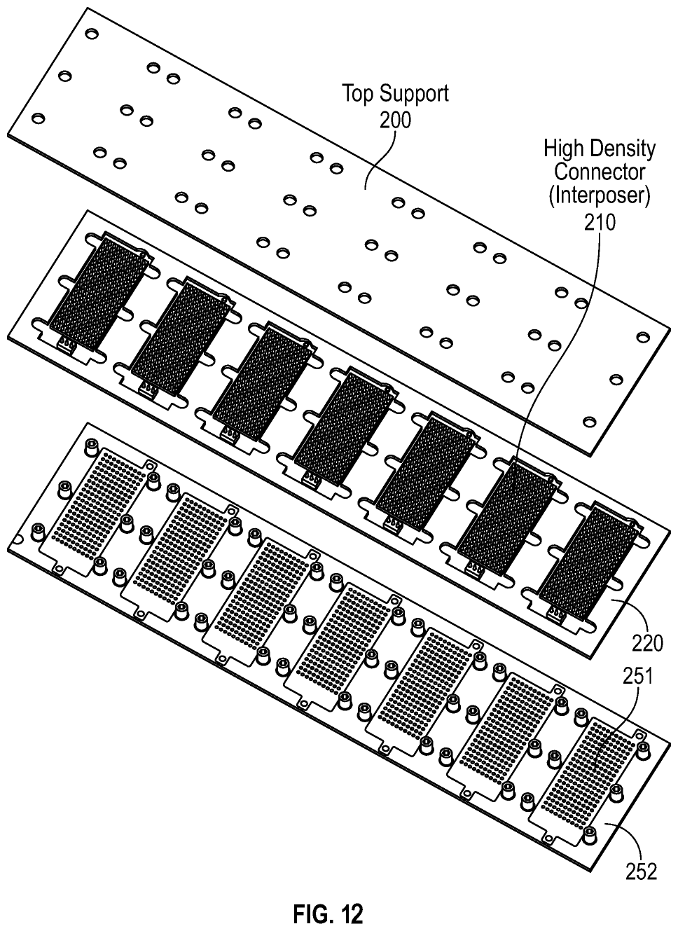

FIG. 12 illustrates an example of a series of pads such as pads 251 on a bottom PCB 252. All springs on all interposers must align with all such pads on the PCB for a correct connection to be made. An spacer layer 220 is positioned around several interposers 210. As shown, there is mechanical separation (equivalent to character 38 in FIG. 10) between interposers 210 and the spacer layer 220. The overall width of spacer layer 220 and top support 200 may depend on the number of interposers 210 and the design of the upper PCB (not shown) and lower PCB 252. The overall length and width will prevent deflection in the PCBs but not consume PCB board space needed for active components. Top support 200 is illustrated as not yet affixed to the top of spacer layer 220, interposer 210, and upper PCB (not shown) and lower PCB 252. However, holes in top support 200 are illustrated for providing a location for fasteners to be used to cause tension and hold together spacer layer 220, interposer 210, and PCBs. Spacer layer 220 may be made of a material that resists compression, but allows a conductive layer to be added in the center. Top support 200 may be made of a material that is stiff enough to prevent deflections. One example of a material for both is blank PCB board.

Contact pads may be implemented in any suitable manner. Contact pads may be formed by a conductive layer of material of any suitable thickness. Contact pads may be implemented with any suitable width and length dimensions or geometry, such as by square or rectangular shapes.

Interconnections may be implemented in any suitable manner, such as by wires, traces, or vias such as vias. Interconnections may be implemented in any suitable manner to provide an electrical or conductive connection from one surface to another surface.

Connectors may be implemented in any suitable manner, such as by spring contacts or bump contacts. Connectors may be implemented by any suitable conductive material. In one embodiment, connectors may be implemented by material shaped to separate but electrically connect two surfaces.

Spacer elements and stiffener supports may be implemented in any suitable manner to maintain separation between two surfaces. For example, spacer elements and stiffener supports may be implemented by layers of non-conductive thickness that is suitable thick to maintain separation between two surfaces. Spacer elements and stiffener supports may have a length and width that is sufficiently small to avoid interference with other mechanisms of the system.

Fasteners may be implemented in any suitable manner to affix one layer of the system to another layer. Fasteners may include solder, or materials that run through the two layers, affixing the layers from the distal end thereof.

Examples of the invention may prevent PCB warping when high density connections are used in close proximity, by using a spacer element and/or a stiffener support. Connection reliability may be increased due to correct spacer design. Transmission characteristics of PCB traces may be more predictable when multiple high density connectors are used in close proximity with spacer layers. Crosstalk and interference between signals may be reduced on the connected PCBs. EMI radiation may be reduced for the connected PCBs.

Although the disclosed embodiments are described in detail in the present disclosure, it should be understood that various changes, substitutions and alterations can be made to the embodiments without departing from their spirit and scope. Those in the art will understand that a number of variations may be made in the disclosed embodiments, all without departing from the spirit and scope of the invention, which is defined solely by the appended claims.

What is claimed is:

1. A system, comprising:
a top printed circuit (PCB) including an array of contact pads;
a bottom PCB including an array of contact pads;
at least one interposer positioned between the top and bottom PCBs, including:
an array of top connectors configured to contact the array of contact pads of the top PCB;
an array of bottom connectors configured to contact the array of contact pads of the bottom PCB; and
interconnections configured to electrically connect the top connectors and the bottom connectors; and
at least one spacer element positioned between the top PCB and the bottom PCB and configured to contribute to maintaining a specified distance between the top PCB and the bottom PCB.

2. The system of claim 1, wherein the spacer layer is configured to inhibit warping of the top PCB or the bottom PCB.

3. The system of claim 1, wherein the array of top connectors comprises spring contacts, and wherein the array of bottom connectors comprises spring contacts.

4. The system of claim 1, wherein at least one of the array of top connectors and the array of bottom connectors comprises bump contacts.

5. The system of claim 1, wherein the specified distance maintained by the at least one spacer element enables an electrical connection between the connectors of the interposer and the contact pads of the top PCB and the bottom PCB when fastened together by at least one fastener.

6. The system of claim 1, wherein at least one spacer element comprises: a top spacer element between the top PCB and the at least one interposer, and a bottom spacer element between the at least one interposer and the bottom PCB.

7. The system of claim 1, wherein at least one interposer comprises a floating interposer.

8. The system of claim 1, wherein the spacer element includes a conductive layer.

9. The system of claim 1, wherein the spacer element includes a PCB.

10. The system of claim 1 further comprising a stiffening support positioned to support at least one of the top and bottom PCBs.

11. The system of claim 10, wherein the stiffening support is configured to inhibit warping of the at least one of the top PCB and the bottom PCB.

12. The system of claim 1, wherein the spacer element is coextensive with the top PCB.

13. The system of claim 10, further comprising one or more fasteners configured to squeeze the stiffener support, the top PCB, the at least one interposer, the bottom PCB, and the at least one spacer element together.

14. The system of claim 10, wherein the stiffener support includes a conductive layer.

15. The system of claim 10, wherein the stiffener support comprises a material similar to a material of a PCB.

16. The system of claim 10, wherein the stiffener support is configured to block EMI radiation for at least one of the top PCB and the bottom PCB.

17. The system of claim 1, wherein the spacer element is configured to block EMI radiation for at least one of the top PCB and the bottom PCB.

18. A method of assembling elements in a socket cavity, the method comprising:
positioning a bottom printed circuit (PCB) including an array of contact pads;
positioning at least one interposer above the bottom PCB, wherein the at least one interposer comprises:
an array of top connectors configured to contact the array of contact pads of the top PCB;
an array of bottom connectors configured to contact the array of contact pads of the bottom PCB; and
interconnections configured to electrically connect the top connectors and the bottom connectors;
positioning at least one spacer element above the bottom PCB;
positioning a top PCB, including an array of contact pads, above the at least one spacer element; and
fastening the top PCB and the bottom PCB so that the at least one spacer element maintains a specified distance of separation between the top and bottom PCBs.

19. The method of claim 18, further comprising positioning a stiffening support to support at least one of the top and bottom PCBs, and said fastening the top PCB and the Bottom PCB further comprises fastening the stiffening support.

20. A socket cavity configured to engage with a top printed circuit board (PCB) and a bottom PCB, each of the PCBs including an array of contact pads, the socket cavity comprising:
an array of top spring connectors configured to contact the array of contact pads of the top PCB;
an array of bottom spring connectors configured to contact the array of contact pads of the bottom PCB; and
interconnections configured to electrically connect the top connectors and the bottom connectors; and
at least one spacer element positioned between the top PCB and the bottom PCB and configured to contribute to maintaining a specified distance between the top PCB and the bottom PCB.
